(19) United States
(12) Patent Application Publication
(10) Pub. No.: US 2026/0371545 A1
(43) Pub. Date: Nov. 19, 2026

(54) COMPONENT MOUNTING SYSTEM

(71) Applicant: FUJI CORPORATION, Chiryu (JP)

(72) Inventors: Hiroyoshi SUGITA, Kariya-shi (JP); Kazuya FUKAO, Toyota-shi (JP)

(73) Assignee: FUJI CORPORATION, Chiryu (JP)

(21) Appl. No.: 19/153,819

(22) PCT Filed: Mar. 7, 2023
(86) PCT No.: PCT/JP2023/008435

§ 371 Date: Aug. 5, 2025

(51) Int. Cl. H05K 13/08

(52) U.S. Cl. CPC H05K 13/0882

(57) ABSTRACT

A component mounting system includes a collection section; a horizontal moving section; a lifting and lowering section; a determination section to determine an operation condition for determining an operation trajectory including a first operation condition such that the mounting target component does not interfere with another member including a pre-mounted component mounted on the board before the mounting target component based on a height of the other member and a distance from the mounting position to a position of the other member, and a second operation condition such that the mounting target component does not interfere with the other member, regardless of the distance from the mounting position to the position of the other member, based on the height of the other member; and a mounting control section to control the horizontal moving section and the lifting and lowering section in accordance with the determined operation trajectory.

### TECHNICAL FIELD

The present description discloses a component mounting system.

### BACKGROUND ART

Conventionally, there is known a component mounter that mounts a component at a mounting position of a board, the component mounter including a nozzle capable of descending and moving horizontally, in which, after the component is collected (picked up) by the nozzle, the nozzle starts to descend just before the mounting position, and the nozzle moves to the mounting position while descending and mounts the component at the mounting position. For example, Patent Literature 1 discloses a method for selecting the shortest route among routes that do not interfere with pre-mounted components mounted before a mounting target component within a decision region centered on a mounting position of the mounting target component, based on a height of the highest component among the pre-mounted components, and for moving a nozzle along the selected route.

### CITATION LIST

### Patent Literature

Patent Literature 1: Wo 2022/030008

Incidentally, in such a component mounter, the pre-mounted component may be mounted at a position deviated from a planned mounting position, or a component with a large dimensional tolerance may be mounted. In such a case, when the nozzle is moved along the shortest route described above, the nozzle or the component picked up by the nozzle may interfere with the pre-mounted component.

A main object of the present disclosure is to shorten the time required for mounting a mounting target component on a board while avoiding interference with other members including a pre-mounted component.

A component mounting system of the present disclosure is a component mounting system for mounting a component on a board, the component mounting system including:
a collection section configured to collect a mounting target component;
a horizontal moving section configured to move the collection section horizontally;
a lifting and lowering section configured to lift and lower the collection section;
a determination section configured to determine, as an operation condition for determining an operation trajectory that is a combination of descending and horizontal movement of the collection section when mounting the mounting target component at a mounting position on the board, one of multiple operation conditions including a first operation condition for determining the operation trajectory such that the mounting target component does not interfere with another member including a pre-mounted component mounted on the board before the mounting target component based on a height of the other member and a distance from the mounting position to a position of the other member, and a second operation condition for determining the operation trajectory such that the mounting target component does not interfere with the other member, regardless of the distance from the mounting position to the position of the other member, based on the height of the other member; and
a mounting control section configured to determine the operation trajectory based on the operation condition determined by the determination section and perform a mounting operation for controlling the horizontal moving section and the lifting and lowering section such that the collection section operates in accordance with the determined operation trajectory to mount the mounting target component at the mounting position.

In this component mounting system, by determining an appropriate condition according to a situation from among the multiple operation conditions including the first operation condition and the second operation condition, it is possible to shorten the time required for mounting the mounting target component on the board while avoiding interference with other members including the pre-mounted component.

### BRIEF DESCRIPTION OF DRAWINGS

FIG. 1 is a schematic configuration diagram of component mounting system 1.

FIG. 2 is a schematic configuration diagram of component mounter 10.

FIG. 3 is a schematic configuration diagram of head 40.

FIG. 4 is a block diagram illustrating an electric connection relationship of component mounting system 1.

FIG. 5A is a flowchart illustrating an example of a component mounting process.

FIG. 5B is a flowchart illustrating the example of the component mounting process.

FIG. 5C is a flowchart illustrating the example of the component mounting process.

FIG. 6 is a diagram illustrating an example of production data 103A.

FIG. 7 is a flowchart illustrating an example of pickup state inspection processing.

FIG. 8 is a diagram illustrating an example of first operation trajectory determination table 103B.

FIG. 9 is a diagram illustrating an example of second operation trajectory determination table 103C.

FIG. 10 is a flowchart illustrating an example of operation condition determination processing.

### DESCRIPTION OF EMBODIMENTS

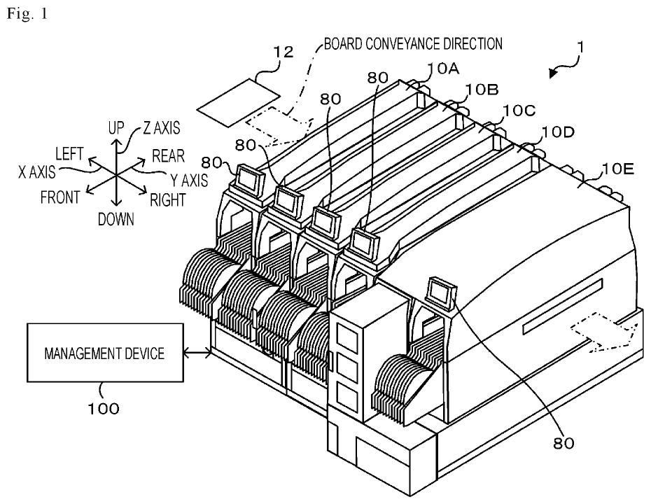

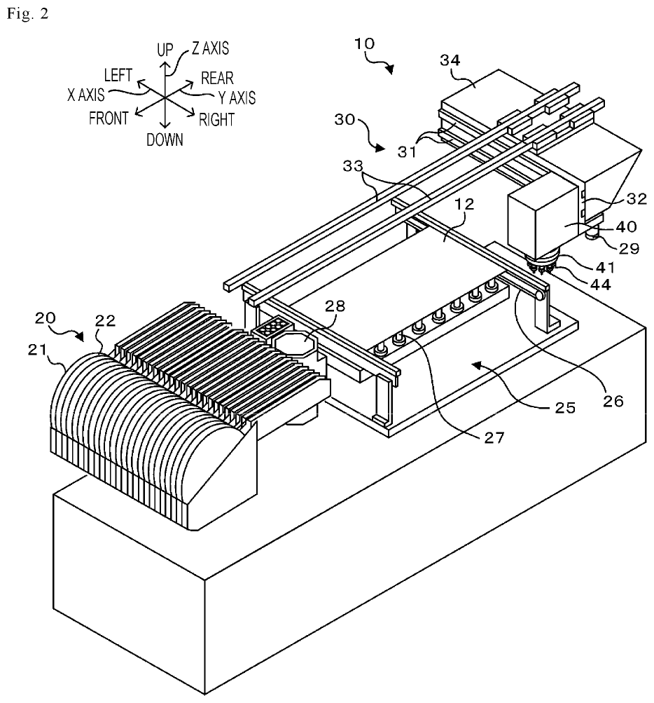

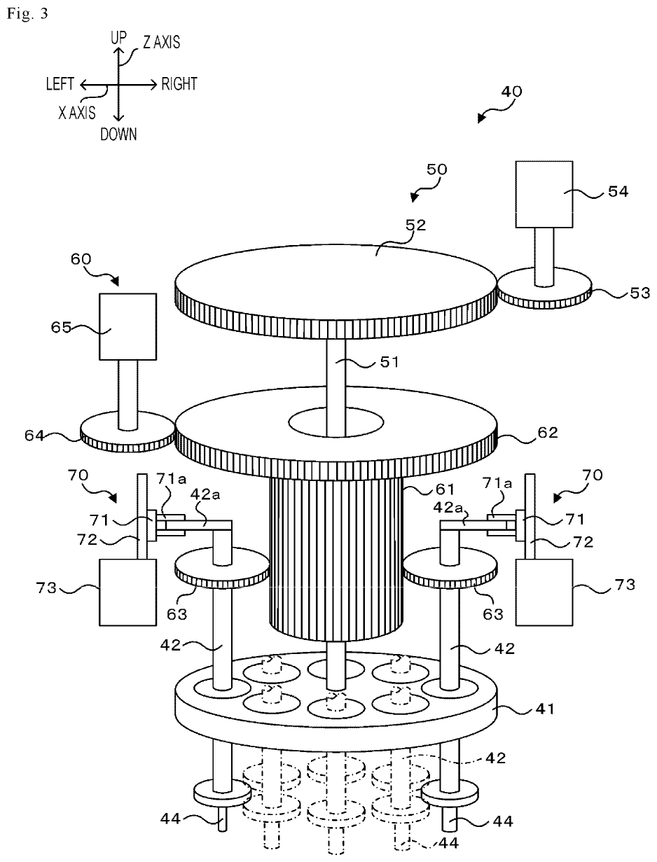

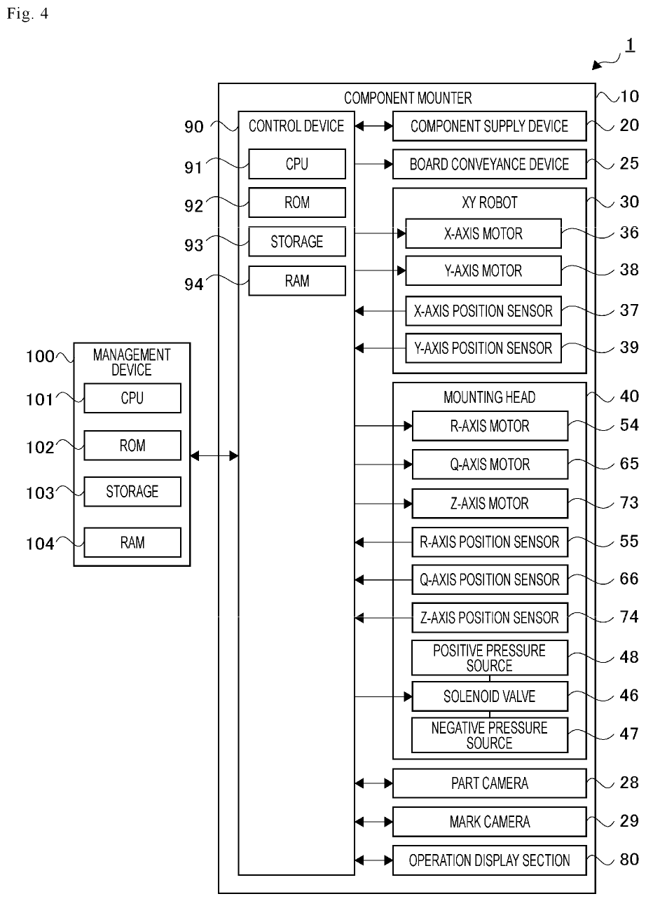

Next, embodiments of the present disclosure will be described with reference to the drawings. FIG. 1 is a schematic configuration diagram of component mounting system 1. FIG. 2 is a schematic configuration diagram of component mounter 10. FIG. 3 is a schematic configuration diagram of head 40. FIG. 4 is a block diagram illustrating an electric connection relationship of component mounting system 1. In FIG. 1, a left-right direction is an X-axis direction, a front (near side)-rear (far side) direction is a Y-axis direction, and an up-down direction is a Z-axis direction.

As illustrated in FIG. 1, component mounting system 1 includes multiple component mounters 10 (component mounters 10A to 10E in the present embodiment) arranged along a conveyance direction of board 12, and management device 100. As illustrated in FIG. 2, component mounter 10 includes component supply device 20 that supplies component P to a component supply position, board conveyance device 25 that conveys board 12, head 40 that collects component P supplied to the component supply position and mounts component P on board 12, and XY robot 30 that moves head 40 in X- and Y-axis directions. In addition, component mounter 10 also includes part camera 28 for imaging the posture of component P picked up by head 40, mark camera 29 for imaging a mark attached to board 12 or component P mounted on board 12, operation display section 80, and control device 90 (see FIG. 4) that controls the entire device.

As illustrated in FIG. 2, multiple component supply devices 20 are provided at a front side of component mounter 10 in such a manner as to be arranged in the left-right direction (X-axis direction). Component supply device 20 is configured as a tape feeder that supplies component P to the component supply position by pulling out tape 22 containing component P from reel 21 at predetermined intervals.

As illustrated in FIG. 2, board conveyance device 25 includes pair of conveyor belts 26 and 26 (only one is illustrated in FIG. 2) that are spaced apart from each other in a front-rear direction while spanning in the left-right direction. Board 12 is conveyed by conveyor belts 26 and 26. When board 12 is conveyed, board 12 is supported by a large number of support pins 27 erected on the back surface side.

As illustrated in FIG. 2, XY robot 30 includes pair of left and right Y-axis guide rails 33 and 33 provided along the front-rear direction (Y-axis direction) and Y-axis slider 34 spanning over pair of left and right Y-axis guide rails 33 and 33. In addition, XY robot 30 includes X-axis guide rails 31 and 31 provided on a front surface of Y-axis slider 34 along the left-right direction (X-axis direction) and X-axis slider 32 attached to X-axis guide rails 31 and 31. X-axis slider 32 is movable in the X-axis direction by being driven by X-axis motor 36 (see FIG. 4), and Y-axis slider 34 is movable in the Y-axis direction by being driven by Y-axis motor 38 (see FIG. 4). A position of X-axis slider 32 in the X-axis direction is detected by X-axis position sensor 37 (see FIG. 4), and a position of Y-axis slider 34 in the Y-axis direction is detected by Y-axis position sensor 39 (see FIG. 4). Head 40 is attached to X-axis slider 32. Head 40 is moved to any position on an XY plane by driving and controlling XY robot 30.

As illustrated in FIG. 3, head 40 includes head main body 41, nozzle holders 42, and nozzles 44. Head main body 41 is a disk-like rotating body. Multiple (here, eight) nozzle holders 42 are provided at predetermined intervals in a circumferential direction of head main body 41. Nozzles 44 are replaceably attached to tip portions of nozzle holders 42. In addition, head 40 includes R-axis drive device 50, Q-axis drive device 60, and Z-axis drive devices 70 and 70. In FIG. 3, for the sake of convenience, two nozzle holders 42 that are in positions to be engaged with Z-axis drive devices 70 and 70 are indicated by solid lines, while remaining nozzle holders 42 are indicated by one-dot chain lines.

R-axis drive device 50 includes R-axis shaft 51, R-axis motor 54, and R-axis position sensor 55 (see FIG. 4). R-axis shaft 51 extends in the up-down direction, and has a lower end attached to a center shaft of head main body 41. R-axis motor 54 rotationally drives gear 53 meshing with R-axis gear 52 provided at an upper end of R-axis shaft 51. R-axis position sensor 55 detects a rotational position of R-axis motor 54. R-axis drive device 50 rotationally drives R-axis shaft 51 via gear 53 and R-axis gear 52 using R-axis motor 54, thereby revolving (turning in circle) multiple nozzle holders 42 supported by head main body 41 in the circumferential direction together with multiple nozzles 44. That is, nozzle 44 intermittently rotates at predetermined intervals.

Q-axis drive device 60 includes upper and lower Q-axis gears 61 and 62 of two stages, gears 63 and 64, Q-axis motor 65, and Q-axis position sensor 66 (see FIG. 4). Upper and lower Q-axis gears 61 and 62 of two stages are inserted coaxially and relatively rotatably with respect to R-axis shaft 51. Gear 63 is provided at an upper portion of each nozzle holder 42 and meshes with lower Q-axis gear 61 so as to be slidable in the up-down direction. Q-axis motor 65 rotationally drives gear 64 meshing with upper Q-axis gear 62. Q-axis position sensor 66 detects a rotational position of Q-axis motor 65. Q-axis drive device 60 rotationally drives Q-axis gears 61 and 62 using Q-axis motor 65, thereby rotating gear 63 meshing with Q-axis gear 61 to rotate each nozzle holder 42 around its central axis in the same rotational direction by the same rotation amount. Along with this, nozzle 44 also rotates (turns around on its central axis).

Z-axis drive devices 70 and 70 are provided at two locations on the revolution (circular turning) trajectory of nozzle holders 42 and can lift and lower nozzle holders 42 individually at the two locations. In the present embodiment, Z-axis drive devices 70 and 70 laterally face each other across the center of head main body 41. Z-axis drive device 70 includes Z-axis slider 71, Z-axis motor 73, and Z-axis position sensor 74 (see FIG. 4). Z-axis slider 71 is attached to ball screw 72 extending in the up-down direction in a liftable and lowerable manner. Z-axis slider 71 includes clamping section 71a that clamps engagement piece 42a extending laterally from nozzle holder 42. Z-axis motor 73 lifts and lowers Z-axis slider 71 by rotating ball screw 72. Z-axis position sensor 74 detects a lifting and lowering position of Z-axis slider 71. Z-axis drive device 70 drives Z-axis motor 73 to lift and lower Z-axis slider 71 along ball screw 72 to lift and lower nozzle holder 42 and nozzle 44 integrated with Z-axis slider 71. When nozzle holder 42 rotates together with head main body 41 and stops at the location where Z-axis drive device 70 is disposed, engagement piece 42a of nozzle holder 42 is clamped by clamping section 71a of Z-axis slider 71. In addition, when nozzle holder 42 moves from the location where Z-axis drive device 70 is disposed, engagement piece 42a of nozzle holder 42 comes out of clamping section 71a of Z-axis slider 71.

Negative pressure source 47 (see FIG. 4) such as a vacuum pump and positive pressure source 48 (see FIG. 4) such as a compressor are selectively connected to nozzle 44 via solenoid valve 46 (see FIG. 4). By operating solenoid valve 46 such that nozzle 44 is connected to negative pressure source 47, negative pressure is applied to nozzle 44, and component P can be picked up (collected). In addition, by operating solenoid valve 46 such that nozzle 44 is connected to positive pressure source 48, component P picked up by nozzle 44 can be mounted on board 12.

As illustrated in FIG. 2, part camera 28 is a camera having an imaging range in the up direction. Part camera 28 is provided between component supply device 20 and board conveyance device 25. When nozzle 44 that has picked up component P passes above part camera 28, part camera 28 captures an image of component P picked up by nozzle 44 and outputs the image to control device 90 (see FIG. 4).

Mark camera 29 is a camera having an imaging range in the down direction. Mark camera 29 is attached to X-axis slider 32. Mark camera 29 images a fiducial mark included in component supply device 20 or images a fiducial mark provided on board 12 or component P mounted on board 12, and outputs the image to control device 90 (see FIG. 4).

Operation display section 80 is a touch panel display for displaying various information such as operation information and error information of component mounter 10, and for receiving an operation of an operator and outputting an operation signal to control device 90. In the present embodiment, operation display section 80 can also edit information on component P to be mounted by component mounter 10 through the operation of the operator.

As illustrated in FIG. 4, control device 90 is configured as a computer mainly including CPU 91, and includes ROM 92, storage (HDD or SSD) 93, RAM 94, and the like in addition to CPU 91. Detection signals from X-axis position sensor 37, Y-axis position sensor 39, R-axis position sensor 55, Q-axis position sensor 66, and Z-axis position sensors 74 and 74, image signals from part camera 28 and mark camera 29, and signals from operation display section 80 are input to control device 90. In addition, control device 90 outputs control signals to component supply device 20, board conveyance device 25, X-axis motor 36, Y-axis motor 38, R-axis motor 54, Q-axis motor 65, Z-axis motors 73 and 73, part camera 28, mark camera 29, and the like, images to be displayed on operation display section 80, and the like.

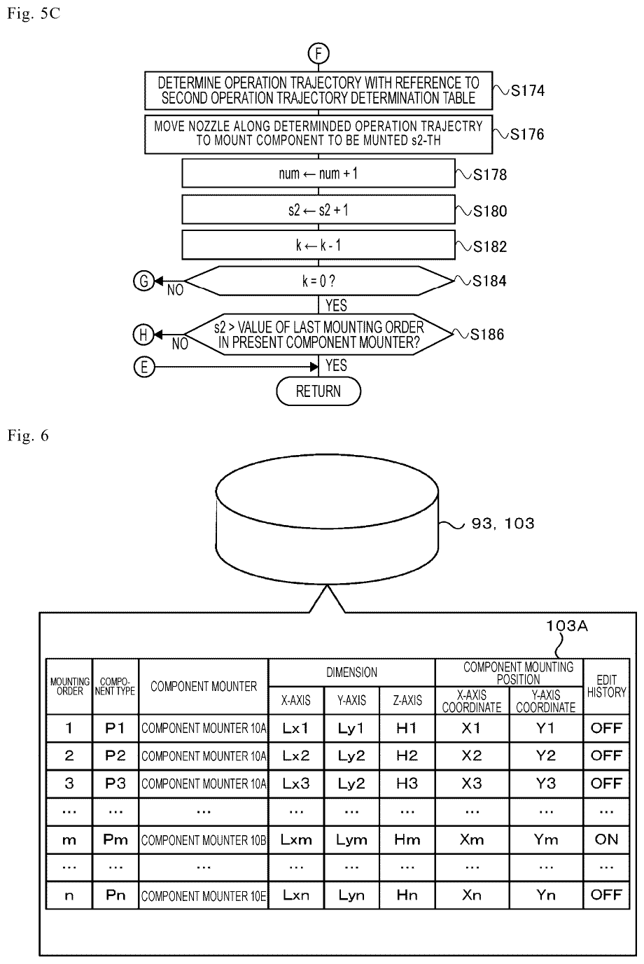

As illustrated in FIG. 4, management device 100 is configured as a computer mainly including CPU 101, and includes ROM 102, storage (HDD or SSD) 103, RAM 104, and the like in addition to CPU 101. Management device 100 stores various information necessary for producing board 12, such as production data 103A. As illustrated in FIG. 6, production data 103A includes a production schedule indicating which types of components P are to be mounted at which positions (mounting position) on board 12 in what order (mounting order), how many boards 12 each having components P mounted thereon are to be produced, shape data relating to dimensions of components P to be mounted, and the like. Here, the mounting position includes a value of an X-axis coordinate and a value of a Y-axis coordinate when a mounting surface of board 12 is regarded as an XY plane. The dimensions of component P include a length in the X-axis direction, a length in the Y-axis direction, a height in the Z-axis direction, and the like. Management device 100 optimizes the mounting order based on the predetermined mounting position and the shape data, and determines of an operation condition based on the optimized mounting order. The operation condition is a condition for determining an operation trajectory of nozzle 44 when mounting component P on board 12. In addition, management device 100 is communicably connected to each of control devices 90 of component mounters 10A to 10E. Management device 100 creates a job including production data 103A and transmits the job to each of control devices 90 of component mounters 10A to 10E, thereby instructing each of component mounters 10A to 10E to produce board 12.

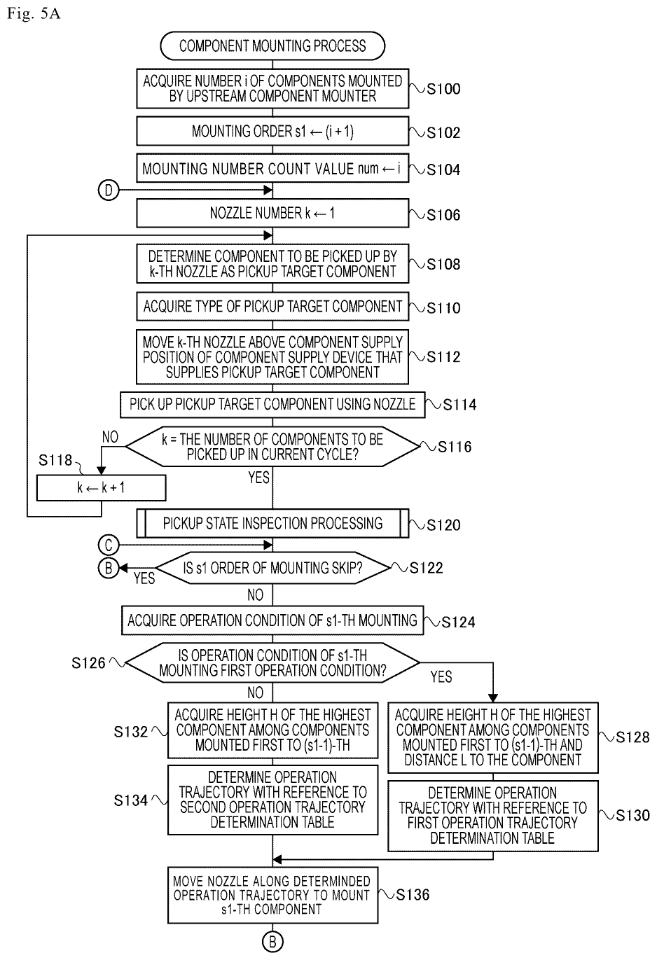

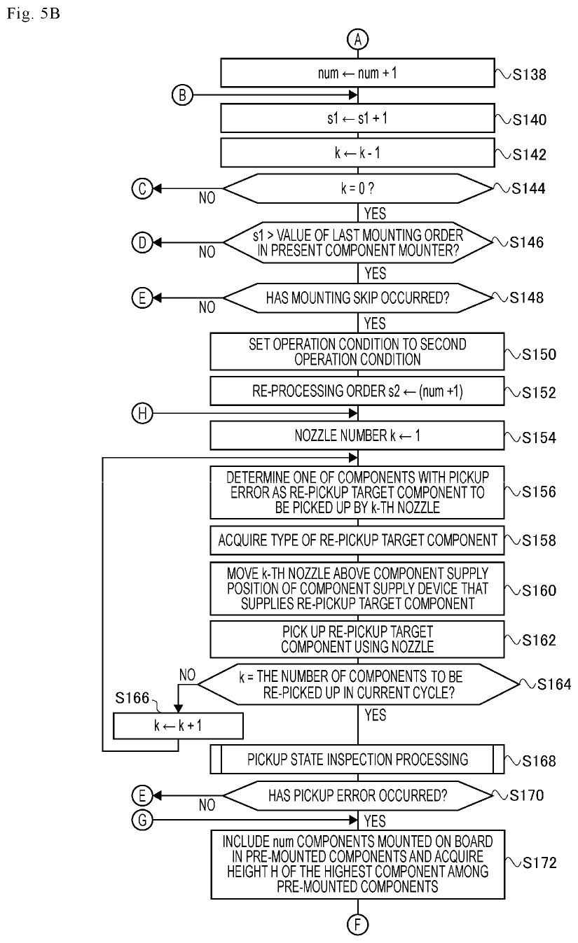

Next, an operation of component mounting system 1 configured as described above will be described. First, a component mounting process performed by component mounter 10 (component mounters 10A to 10E) will be described with reference to FIGS. 5A to 5C and FIGS. 6 to 9. In each of component mounters 10A to 10E, the component mounting process is executed by CPU 91 after the job is received from management device 100 and production data 103A included in the received job is stored in storage 93. In the present embodiment, an operation of picking up components P using one or more of multiple nozzles 44 included in one head 40 and mounting all of components P picked up by head 40 on board 12 is referred to as a “cycle”. In production data 103A stored in storage 93, the mounting position and the dimensions of designated component P may be edited through the operator's operation of operation display section 80 at a predetermined timing after component P to be mounted by present component mounter 10 is mounted. This is to finely adjust the mounting position or the like of component P when a positional deviation occurs in component P mounted on board 12. Details will be described below.

When the present process is started, CPU 91 acquires number i of mounted components, which is the number of components P mounted on one board 12 by component mounter 10 disposed upstream of present component mounter 10 (component mounter 10 that executes the present process) in a board conveyance direction, based on production data 103A as illustrated in FIG. 6 (S100). When the component mounting process is executed in component mounter 10A located on the most upstream side, number i of mounted components is a value of 0. Subsequently, CPU 91 sets a value obtained by adding a value of 1 to number i of mounted components to mounting order s1 of component P to be mounted this time among multiple (n) components P to be mounted on one board 12 by entire component mounting system 1 (S102). Next, CPU 91 sets number i of mounted components to mounting number count value num, which is the number of components P that have been mounted on one board 12 by component mounting system 1, including present component mounter 10 (S104). Then, CPU 91 sets a value of nozzle number k to 1 (S106).

Next, CPU 91 determines component P to be picked up by k-th nozzle 44 in the current cycle as a pickup target component (S108). Subsequently, CPU 91 acquires a component type of the pickup target component from production data 103A (S110). Then, CPU 91 moves nozzle 44 above the component supply position in component supply device 20 that supplies the pickup target component (S112). Specifically, R-axis motor 54 is controlled so that k-th nozzle 44 moves to a position where k-th nozzle 44 engages with Z-axis drive device 70. Next, CPU 91 controls X-axis motor 36 and Y-axis motor 38 so that nozzle 44 moves to a position above the component supply position while obtaining the position of nozzle 44 based on the input signals from X-axis position sensor 37 and Y-axis position sensor 39.

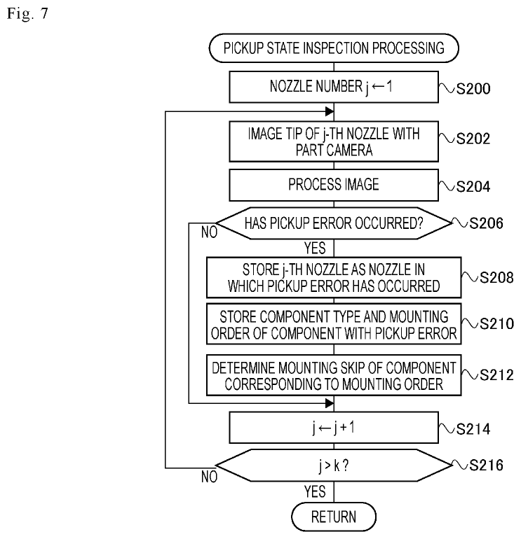

Next, CPU 91 causes k-th nozzle 44 to pick up the pickup target component (S114). Specifically, CPU 91 controls Z-axis motor 73 so that nozzle 44 descends, and controls solenoid valve 46 so that negative pressure source 47 is connected to nozzle 44 and a negative pressure is applied to nozzle 44. When nozzle 44 descends and comes into contact with an upper surface of the pickup target, nozzle 44 picks up the pickup target component with a negative pressure. Subsequently, CPU 91 decides whether a value of nozzle number k matches the number of components to be picked up in the current cycle (S116). When it is decided in S116 that the value of nozzle number k is less than the number of components to be picked up in the current cycle, CPU 91 increments the value of nozzle number k by 1 (S118). After S118, CPU 91 returns to S108 again, determines component P to be picked up by next nozzle 44 as the pickup target component, and repeats the pickup operation. When it is decided in S116 that the value of nozzle number k matches the number of components to be picked up in the current cycle, CPU 91 determines that all components P to be picked up in the current cycle have been picked up, and executes pickup state inspection processing illustrated in FIG. 7.

When the pickup state inspection processing is started, CPU 91 sets a value of nozzle number j to 1 (S200). Next, CPU 91 images a tip of j-th nozzle 44 with part camera 28 (S202). Specifically, CPU 91 controls X-axis motor 36 and Y-axis motor 38 so that j-th nozzle 44 moves to a position above part camera 28, and then controls part camera 28 so that an image of the tip of j-th nozzle 44 is captured. Part camera 28 may collectively image multiple nozzles 44 at one time. Subsequently, CPU 91 performs predetermined image processing on the image captured in S202 (S204). Then, CPU 91 decides whether a pickup error has occurred (S206). This process is performed, for example, as follows. That is, CPU 91 performs a process of recognizing component P from the captured image and specifying a position of component P. When component P is captured in the image and the positional deviation amount of captured component P is within an allowable range, CPU 91 decides that no pickup error has occurred. When component P is not captured in the image or when component P is captured in the image but the positional deviation amount of component P exceeds the allowable range, CPU 91 decides that the pickup error has occurred. When it is decided in S206 that no pickup error has occurred, CPU 91 proceeds to S214.

When it is decided in S206 that the pickup error has occurred, CPU 91 stores j-th nozzle 44 in storage 93 as nozzle 44 in which the pickup error has occurred (S208). Next, CPU 91 acquires the component type and mounting order s1 of component P that is a target of the pickup error from production data 103A and stores the component type and mounting order s1 in storage 93 (S210). Subsequently, CPU 91 determines mounting skip in which component P planned to be mounted in mounting order s1 acquired in S210 is skipped without being mounted (S212). Then, CPU 91 increments the value of nozzle number j by 1 (S214).

Next, CPU 91 decides whether the value of nozzle number j is greater than the value of nozzle number k (S216). Here, since nozzle number k is incremented by a value of 1 every time the pickup operation is executed in S108 to S118 with a value of 1 as an initial value, nozzle number k is the number of components picked up in the current cycle. When it is decided that the value of nozzle number j is equal to or less than the value of nozzle number k, CPU 91 determines that there is still nozzle 44 for which the occurrence of the pickup error has to be checked, and returns to S202 again to image the tip of next nozzle 44 with part camera 28. When it is decided in S216 that the value of nozzle number j is greater than the value of nozzle number k, CPU 91 determines that the presence or absence of the pickup error has been confirmed for all nozzles 44 that have picked up components P in the current cycle, ends the present processing, and proceeds to S122 of the component mounting process illustrated in FIG. 5A.

Next, CPU 91 decides whether the s1-th mounting order is a mounting order of the mounting skip (S122). Specifically, CPU 91 decides whether the s1-th mounting order is the mounting order determined to be the mounting skip in S210 and S212 of the pickup state inspection processing. When it is decided in S122 that the s1-th mounting order is the mounting order of the mounting skip, CPU 91 proceeds to S140. On the other hand, when it is decided that the s1-th mounting order is not the mounting order of the mounting skip, CPU 91 acquires the operation condition of the mounting operation for component P to be mounted in the s1-th mounting order from management device 100 (S124). The operation trajectory of nozzle 44 determined based on the acquired operation conditions is determined by a combination of the lifting and lowering of nozzle 44 through the driving of Z-axis motor 73 and the horizontal movement of nozzle 44 through the driving of X-axis motor 36 and Y-axis motor 38. For example, the operation trajectory includes a trajectory in which nozzle 44 is horizontally moved to directly above the mounting position and then nozzle 44 descends such that component P comes into contact with board 12 at the mounting position, and a trajectory in which nozzle 44 starts to descend just before the mounting position and then nozzle 44 moves to the mounting position while descending.

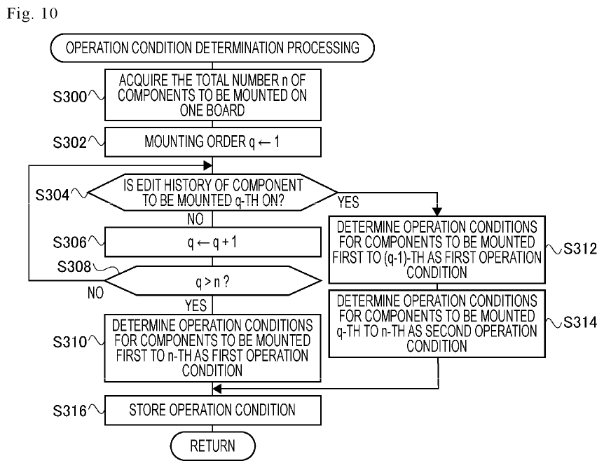

Here, the description of the component mounting process is temporarily suspended, and operation condition determination processing executed by CPU 101 of management device 100 will be described with reference to FIG. 10. This processing is executed by CPU 101 of management device 100 when a new job (production data 103A) is created or when information indicating that any component P has been on-machine edited is received from control device 90 of each component mounter 10.

When the present processing is started, CPU 101 first acquires total number n of components to be mounted on one board 12 by entire component mounting system 1 based on production data 103A illustrated in FIG. 6 (S300). Next, CPU 101 sets a value of mounting order q to 1 (S302). Subsequently, CPU 101 decides whether an edit history of component P to be mounted q-th is ON (S304).

Here, the edit history is a history of on-machine editing performed by the operator (worker) on operation display section 80 included in component mounter 10. In addition, the on-machine editing is a process for finely correcting the mounting position (values of the X-axis coordinate and the Y-axis coordinate) and the dimensions (each length in the X-axis direction, the Y-axis direction, and the Z-axis direction) of component P so that component P is mounted at a planned mounting position or component P having specified dimensions is mounted. After the production of board 12 is completed, a visual inspection device (not illustrated) and mark camera 29 provided in component mounter 10 are used to inspect whether each component P has been mounted in the planned mounting position, whether the dimensions of each component P are within the specified dimensions, or the like. In this inspection, when each component P is mounted at a position deviated from a planned position for some reason or when a dimensional tolerance is large and the dimensions of each component P are different from the specified dimensions, CPU 91 receives input from the operator via operation display section 80 and edits production data 103A on the machine. When the on-machine editing is performed, CPU 91 sets the edit history to ON and transmits the content of the on-machine editing to management device 100. When the content of the on-machine editing is received, CPU 101 of management device 100 temporarily updates production data 103A. For component P whose edit history is ON, the edit history is maintained in the ON state until management device 100 receives a worker's operation and executes optimization of the mounting order again on temporarily updated production data 103A, or until management device 100 discards temporarily updated production data 103A and returns production data 103A to original production data 103A.

If it is decided in S304 that the edit history is not ON but OFF, CPU 101 increments mounting order q by a value of 1 (S306), and then decides whether the value of mounting order q is greater than total number n of components (S308). If it is decided in S308 that the value of mounting order q is equal to or less than total number n of components, CPU 101 returns to S304 and repeats the process of checking the edit history of component P to be mounted in the next mounting order. On the other hand, when it is decided in S308 that the value of mounting order q is greater than total number n of components, CPU 91 determines that the edit history of component P is OFF in all mounting orders, and determines the operation condition for component P to be mounted in all mounting orders (first to n-th) as first operation condition (S310).

When it is decided that the edit history is ON in the q-th mounting order in S304 in the process of repeating S304 to S308, CPU 101 determines the operation conditions for components P to be mounted first to (q−1)-th among total number n of components as first operation condition (S312), and determines the operation conditions for components P to be mounted q-th to n-th as second operation condition (S314). After S310 or S314, CPU 101 stores the determined operation conditions in storage 93 (S316), and ends the present processing. As described above, when the edit history is ON, CPU 101 determines, as the first operation condition, the operation condition for component P to be mounted before an editing target component to be first mounted among editing target components that are targets of on-machine editing, and determines, as the second operation condition, the operation condition for component P to be mounted after the editing target component to be first mounted.

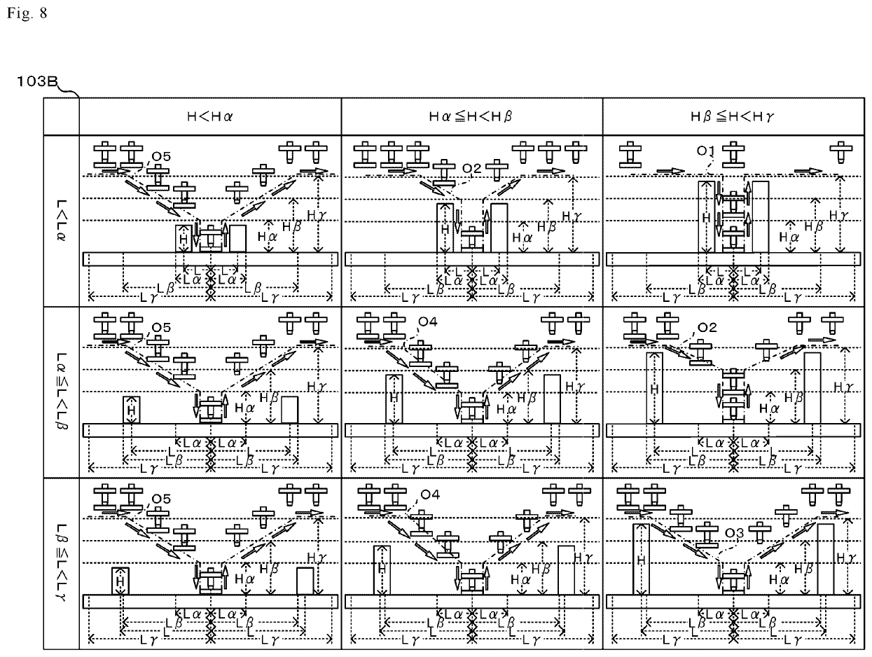

The description returns to the component mounting process. After S124, CPU 91 decides whether the operation condition for component P to be mounted s1-th, which is acquired in S124, is the first operation condition, as illustrated in FIG. 5A (S126). Here, components P to be mounted first to (s1−1)-th are pre-mounted components that are mounted on board 12 before component P to be mounted s1-th. The first operation condition is an operation condition for determining, based on a height of the pre-mounted component and a distance from a mounting position of component P to be mounted s1-th (current mounting target component) to the pre-mounted component, the operation trajectory of nozzle 44 that has picked up the mounting target component. When it is decided in S126 that the operation condition is the first operation condition, CPU 91 acquires height H of the highest pre-mounted component among the pre-mounted components mounted first to (s1−1)-th and distance L from the mounting position of the mounting target component to be mounted s1-th to the highest pre-mounted component (S128). Then, CPU 91 refers to first operation trajectory determination table 103B as illustrated in FIG. 8 to determine the operation trajectory of nozzle 44 that has picked up the mounting target component (S130). Specifically, CPU 101 determines the operation trajectory corresponding to height H and distance L acquired in S128 from first operation trajectory determination table 103B as the operation trajectory of nozzle 44 when mounting the mounting target component. Here, first operation trajectory determination table 103B stores the operation trajectory of nozzle 44 for each combination of height H and distance L. First operation trajectory determination table 103B stores an operation trajectory in which nozzle 44 starts to descend at a position farther from the mounting position of the mounting target component when height H is low than when height H is high. In addition, first operation trajectory determination table 103B stores an operation trajectory in which nozzle 44 starts to descend at a position farther from the mounting position of the mounting target component when distance L is short than when distance L is long. This is because the higher height H is and the shorter distance L is, the more likely nozzle 44 interferes with the pre-mounted component when nozzle 44 starts to descend just before the mounting position. Nozzle 44 starts to descend just before the mounting position within a range in which nozzle 44 does not interfere with the pre-mounted component, whereby the movement distance of nozzle 44 can be shortened while avoiding the interference with the pre-mounted component, and the cycle time can be shortened.

Here, an example of the operation trajectory of nozzle 44 determined based on the first operation condition will be described. In FIG. 8, Hα, Hβ, and Hγ are height thresholds, where Hα<Hβ<Hγ. Lα, Lβ, and Lγ are distance thresholds, where Lα<Lβ<Lγ. First, a case where height H is equal to or greater than height Hβ and less than height Hγ will be described. When distance L from the mounting position of the mounting target component to the highest pre-mounted component is less than distance Lα, CPU 91 determines the operation trajectory of nozzle 44 as first operation trajectory O1. First operation trajectory Ol is an operation trajectory in which nozzle 44 horizontally moves to a position directly above the mounting position and then descends. When distance L is equal to or greater than distance Lα and less than distance Lβ, CPU 91 determines the operation trajectory of nozzle 44 as second operation trajectory O2. Second operation trajectory O2 is an operation trajectory in which nozzle 44 starts to descend from a position farther from the mounting position than in first operation trajectory O1. When distance L is equal to or greater than distance Lβ and less than distance Lγ, CPU 91 determines the operation trajectory of nozzle 44 as third operation trajectory O3. Third operation trajectory O3 is an operation trajectory in which nozzle 44 starts to descend from a position even farther from the mounting position than in second operation trajectory O2. Next, a case where height H is equal to or greater than height Hα and less than height Hβ will be described. When distance L is less than distance Lα, CPU 91 determines the operation trajectory of nozzle 44 as second operation trajectory O2. When distance L is equal to or greater than distance Lα and less than distance Lβ, CPU 91 determines the operation trajectory of nozzle 44 as fourth operation trajectory O4. Fourth operation trajectory O4 is an operation trajectory in which nozzle 44 starts to descend from a position even farther from the mounting position than in third operation trajectory O3. When distance L is equal to or greater than distance Lβ and less than distance Lγ, CPU 91 determines the operation trajectory of nozzle 44 as fourth operation trajectory O4. Then, when height H is less than height Hα, CPU 91 determines the operation trajectory of nozzle 44 as fifth operation trajectory O5. Fifth operation trajectory O5 is an operation trajectory in which nozzle 44 starts to descend from a position even farther from the mounting position than in fourth operation trajectory O4.

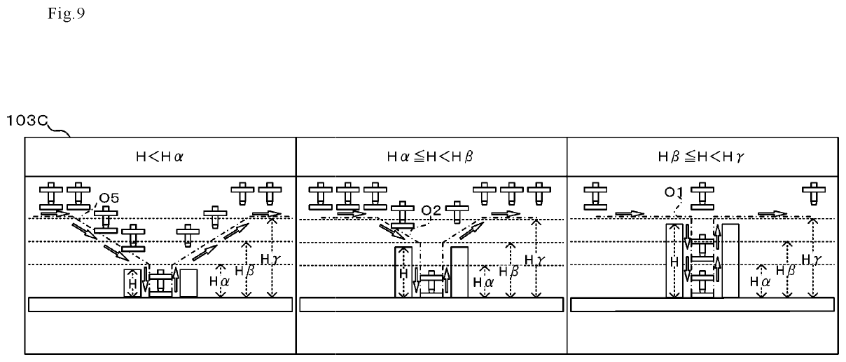

When it is decided in S126 that the operation condition is not the first operation condition (is the second operation condition), CPU 91 acquires height H of the highest pre-mounted component (S132). The second operation condition is an operation condition for determining the operation trajectory of nozzle 44 based on height H of the highest pre-mounted component. Next, CPU 101 refers to second operation trajectory determination table 103C as illustrated in FIG. 9 to determine the operation trajectory of nozzle 44 that picks up the target component (S134). Specifically, CPU 101 determines the operation trajectory corresponding to height H acquired in S132 from second operation trajectory determination table 103C as the operation trajectory of nozzle 44 when mounting the mounting target component. Second operation trajectory determination table 103C stores the same operation trajectory as that when distance L is less than distance Lα in first operation trajectory determination table 103B regardless of distance L from the mounting position of the mounting target component to the highest pre-mounted component. When height H is equal to or greater than height Hβ and less than height Hγ, CPU 91 determines the operation trajectory of nozzle 44 as first operation trajectory O1. When height H is equal to or greater than height Hα and less than height Hβ, CPU 91 determines the operation trajectory of nozzle 44 as second operation trajectory O2. When height H is less than height Hα, CPU 91 determines the operation trajectory of nozzle 44 as fifth operation trajectory O5.

As described above, in the operation trajectory stored in first operation trajectory determination table 103B, nozzle 44 starts to descend closer to the mounting position when distance L from the mounting position of the mounting target component to the highest pre-mounted component is shorter than when distance L is longer. This is to reliably avoid interference with the pre-mounted component. In addition, component P whose edit history is ON is mounted at a position different from the mounting position initially determined in production data 103A, and the distance to the pre-mounted component may be shorter than the initial plan. In this case, when the operation trajectory of nozzle 44 is determined based on first operation trajectory determination table 103B with distance L as the initially planned distance, nozzle 44 or component P picked up by nozzle 44 may interfere with the pre-mounted component. However, in the present embodiment, when the edit history is ON, by determining the same operation trajectory as when distance L is less than distance Lα, even in such a case, it is possible to prevent nozzle 44 or component P picked up by nozzle 44 from interfering with the pre-mounted component. Therefore, second operation trajectory determination table 103C stores the same operation trajectory as that when distance L is less than distance Lα in first operation trajectory determination table 103B regardless of actual distance L.

After S130 or S134, CPU 91 moves nozzle 44 that has picked up the mounting target component along the operation trajectory determined in S130 or S134, and mounts component P in mounting order s1 on board 12 (S136). Specifically, CPU 91 controls R-axis motor 54 so that nozzle holder 42 holding nozzle 44 that has picked up the mounting target component moves to a position where nozzle holder 42 engages with Z-axis drive device 70. Next, CPU 91 controls X-axis motor 36, Y-axis motor 38, and Z-axis motor 73 so that nozzle 44 that has picked up the mounting target component moves along the operation trajectory determined in S130 or S134 while obtaining the position of nozzle 44 based on the input signals from X-axis position sensor 37, Y-axis position sensor 39, and Z-axis position sensor 74. After confirming that the mounting target component has come into contact with board 12, CPU 91 controls solenoid valve 46 so that positive pressure source 48 is connected to nozzle 44. As a result, positive pressure is applied to nozzle 44, the pickup of component P performed by nozzle 44 is released, and component P is mounted on board 12. Next, as illustrated in FIG. 5B, CPU 91 increments mounting number count value num by 1 (S138).

After it is decided in S122 that s1-th is the mounting order of the mounting skip or after S138, CPU 91 increments the value of mounting order s1 by 1 (S140) and decrements the value of nozzle number k by 1 (S142). Next, CPU 91 decides whether the value of nozzle number k is 0 (S144). If it is decided in S144 that the value of nozzle number k is not 0, CPU 91 determines that there is still nozzle 44 that has picked up component P to be processed (mounted or skipped), returns to S122 again, and decides whether mounting order s1 of next component P is the mounting order of the mounting skip. When it is decided in S144 that the value of nozzle number k is 0, CPU 91 determines that the current cycle has ended, and decides whether the value of mounting order s1 is greater than the value of the mounting order in which component P is mounted last by present component mounter 10 (S146). The mounting order in which component P is mounted last by present component mounter 10 can be recognized by referring to production data 103A. When it is decided in S146 that the value of mounting order s1 is equal to or less than the value of the mounting order in which component P is mounted last by present component mounter 10, CPU 91 determines that there is still component P to be processed by present component mounter 10, returns to S106 again, and starts the next cycle.

In component mounting system 1, the operation condition is determined based on the presence or absence of the history of the on-machine editing, so that the operation condition is determined as the first operation condition in the mounting order until the on-machine editing is performed. That is, until the mounting order in which component P that is the target of the on-machine editing is mounted, the operation trajectory of nozzle 44 when mounting component P is determined based on the first operation condition. Therefore, it is possible to sufficiently shorten the operation trajectory of nozzle 44 when mounting the components P on board 12. In addition, in component mounter 10, in the mounting order after the mounting order in which component P that is the target of the on-machine editing is mounted, the operation trajectory of nozzle 44 when mounting component P is determined based on the second operation condition. That is, after the mounting order that is the target of the on-machine editing, the operation trajectory when mounting component P is determined based on the second operation condition. Therefore, even when the mounting position of component P is changed to a position different from that of initial production data 103A or the dimensions of component P are changed due to the on-machine editing, it is possible to more reliably avoid interference between nozzle 44 or component P picked up by nozzle 44 and the pre-mounted component.

When it is decided in S146 that the value of mounting order s1 is greater than the value of the mounting order in which component P is mounted last by present component mounter 10, CPU 91 decides that all components P to be processed by present component mounter 10 have been processed, and decides whether the mounting skip has occurred due to a pickup error (S148). When it is decided in S148 that no mounting skip has occurred, CPU 91 ends the present process. On the other hand, when it is decided in S148 that the mounting skip has occurred, CPU 91 performs a retry operation of re-picking up component P of the same type as component P that has failed to be picked up and mounting component P on board 12. In the retry operation, CPU 91 first sets the operation condition for performing the retry operation to the second operation condition (S150). Next, CPU 91 sets a value obtained by adding a value of 1 to mounting number count value num to re-processing order s2, which is an order when mounting component P that is a target of a pickup error in the pickup state inspection processing executed in S120 (S152). As described above, mounting number count value num is incremented by a value of 1 when mounting of component P is performed, but is not incremented when mounting of component P is skipped. Therefore, re-processing order s2 represents the actual mounting order of components P to be re-picked up. Subsequently, CPU 91 sets the value of nozzle number k to 1 (S154).

Next, CPU 91 determines one of components P that have resulted in pickup error and that require a retry operation as a re-pickup target component (S156). Subsequently, CPU 91 acquires the type of the re-pickup target component (S158). The re-pickup target component is the same type of component as component P that is the target of the pickup error, and CPU 91 determines the re-pickup target component with reference to storage 93. Subsequently, CPU 91 moves k-th nozzle 44 above the component supply position of component supply device 20 that supplies the re-pickup target component as in S112 (S160). Then, CPU 91 causes k-th nozzle 44 to pick up the re-pickup target component as in S114 (S162).

Next, CPU 91 decides whether a value of nozzle number k matches the number of components to be re-picked up in the current cycle (S164). When it is decided in S164 that the value of nozzle number k is equal to or less than the number of components to be re-picked up in the current cycle, CPU 91 increments the value of nozzle number k by 1 (S166), returns to S156, determines the next re-pickup target component, and repeats the re-pickup process. When it is decided in S164 that the value of nozzle number k matches the number of components to be re-picked up in the current cycle, CPU 91 executes the pickup state inspection processing (S168). The pickup state inspection processing is as described above. Subsequently, CPU 91 decides whether a pickup error has occurred in the pickup state inspection processing (S170). When it is decided in step S170 that the pickup error has occurred, CPU 91 interrupts the subsequent mounting process, notifies of the error by displaying an error message on operation display section 80, and ends the present process. The worker who has seen the error message checks the state of corresponding component mounter 10, performs necessary maintenance, and then operates operation display section 80 to perform an operation of resolving the error. When the error is resolved, CPU 91 resumes the mounting process.

When it is decided in step S170 that no pickup error has occurred, CPU 91 includes num (mounting number count value) components already mounted on board 12 in the pre-mounted components. When the pickup of component P fails, the mounting skip of component P occurs, and component P of the same type as component P is re-picked up and mounted on board 12, the pre-mounted components include not only components P mounted on board 12 until the mounting skip occurs but also components P mounted on board 12 until component P re-picked up by the retry operation is mounted on board 12 after the mounting skip occurs. Specifically, since mounting order s1 is incremented by a value of 1 in S140 regardless of whether component P is mounted or skipped, component P excluding component P whose mounting is skipped among first to s1-th components P corresponds to the pre-mounted component. Subsequently, as illustrated in FIG. 5C, CPU 91 refers to second operation trajectory determination table 103C as illustrated in FIG. 9 to determine the operation trajectory of nozzle 44 that has picked up the re-pickup target component (S174). This is the same processing as S134. Then, CPU 91 moves nozzle 44 along the operation trajectory determined in S174 as in S136, and mounts component P in re-processing order s2 on board 12 (S176).

Next, CPU 91 increments the value of mounting number count value num by 1 (S178), increments the value of re-processing order s2 by 1 (S180), and decrements the value of nozzle number k by 1 (S182). Subsequently, CPU 91 decides whether the value of nozzle number k is 0 (S184). When it is decided in S184 that the value of nozzle number k is not 0, CPU 91 determines that there is still nozzle 44 that has re-picked up component P to be mounted on board 12, and returns to S172 again. When it is decided in S184 that the value of nozzle number k is 0, CPU 91 decides that all of components P that have re-picked up in the current cycle have been mounted on board 12, and decides whether the value of re-processing order s2 is greater than the value of the mounting order in which component P is mounted last by present component mounter 10 (S186). When it is decided in S186 that the value of re-processing order s2 is equal to or less than the value of the mounting order in which component P is mounted last by present component mounter 10, CPU 91 determines that there is still component P to be re-picked up, returns to S154 again, and starts the next cycle. On the other hand, when it is decided in S186 that the value of re-processing order s2 is greater than the value of the mounting order in which component P is mounted last by present component mounter 1, CPU 91 determines that all components P to be mounted by present component mounter 10 have been mounted, and ends the present process.

In component mounter 10, when the pickup error occurs, the retry operation is performed by once processing all components P to be processed by present component mounter 10 and then re-picking up component P of the same type as component P that is a target of the pickup error and mounting component P on board 12. Therefore, if the pickup error does not occur, component P to be mounted later may be mounted on board 12 before component P with the pickup error, because the mounting the component P that is the target of the pickup error is skipped. In this case, when the operation trajectory of nozzle 44 is determined for component P re-picked up by the retry operation with only component P mounted on board 12 before the mounting is skipped as the pre-mounted component, since component P that would not have been originally mounted is mounted on board 12 first, nozzle 44 or component P picked up by nozzle 44 may interfere with the pre-mounted component. On the other hand, in component mounter 10 of the present embodiment, CPU 91 determines the operation trajectory of nozzle 44 based on the second operation condition while treating, as the pre-mounted components, components P mounted on board 12 until component P re-picked up by the retry operation is mounted on board 12 after the mounting skip occurs. Therefore, when mounting component P re-picked up by the retry operation, it is possible to more reliably avoid interference between nozzle 44 and the pre-mounted component. When the pickup error occurs, the retry operation may be performed by mounting all components to be mounted in the current cycle and then re-picking up component P of the same type as component P that is a target of the pickup error and mounting component P on board 12.

Here, a correspondence relationship between elements of the embodiment and elements of the present disclosure described in the claims will be described. That is, component mounting system 1 of the present embodiment corresponds to a component mounting system of the present disclosure, XY robot 30 corresponds to a horizontal moving section, Z-axis drive device 70 corresponds to a lifting and lowering section, CPU 101 that executes the operation condition determination processing corresponds to a determination section, and CPU 91 that executes the component mounting process corresponds to a mounting control section. Operation display section 80 corresponds to an editing section. Head 40 corresponds to a head, and part camera 28 and CPU 91 that executes the pickup state inspection processing correspond to a detection section.

It goes without saying that the present disclosure is not limited to the above-described embodiment in any way, and hence can be practiced in various aspects as long as the aspects fall within the technical scope of the present disclosure.

In the above-described embodiment, management device 100 determines the operation condition, and control device 90 acquires the operation condition from management device 100 and determines the operation trajectory. However, the operation trajectory may be determined based on the operation condition determined by management device 100, and control device 90 may acquire the operation trajectory from management device 100. In addition, control device 90 may determine the operation condition and determine the operation trajectory based on the determined operation condition.

In the above-described embodiment, the operation trajectory of nozzle 44 when mounting component P that is the target of the pickup error is determined based on the second operation condition. However, the operation trajectory of nozzle 44 when mounting component P that is the target of the pickup error may be determined based on the first operation condition.

In the above-described embodiment, whether the operation condition is the first operation condition or the second operation condition is determined based on the presence or absence of the history of the on-machine editing. However, the operation condition may be freely determined by the operator.

In the above-described embodiment, in the component mounting process, when it is decided in S170 that the pickup error has occurred even after the retry operation, CPU 91 ends the component mounting process. However, CPU 91 may repeatedly execute the retry operation up to a predetermined number of times of two or more times.

In the above-described embodiment, in first operation trajectory determination table 103B, the threshold of distance L from the mounting position of the mounting target component to the pre-mounted component is divided into three stages: less than Lα, Lα or more and less than Lβ, and Lβ or more and less than Lγ. However, the threshold may be divided into two stages, or may be divided into four or more stages. In addition, in first operation trajectory determination table 103B, the threshold of the height of the pre-mounted component is divided into three stages: less than Hα, Hα or more and less than Hβ, and Hβ or more and less than Hγ. However, the threshold may be divided into two stages, or may be divided into four or more stages.

In the above-described embodiment, CPU 91 of control device 90 determines the operation trajectory of nozzle 44 based on the operation condition acquired in S126 in the component mounting process. However, CPU 91 may acquire production data 103A from management device 100, acquire the operation trajectory determined based on the first operation condition, and re-determine the operation trajectory based on the second operation condition only when the operation condition acquired in S126 is the second operation condition.

In the above-described embodiment, CPU 91 of control device 90 determines, as the first operation condition, the operation trajectory of nozzle 44 in consideration of the distance from the mounting position of the mounting target component to the pre-mounted component and the height of the pre-mounted component. However, CPU 91 may determine the operation trajectory of nozzle 44 in consideration of the distance from the mounting position of the mounting target component to an interfering object (for example, unevenness on board 12) other than the pre-mounted component and the height of the interfering object. In this case, the operator may input the position and the height of the interfering object on board 12 to management device 100.

In the above-described embodiment, component mounter 10 may have, in head 40, a side camera that captures images of nozzle 44 and the pickup state of component P with respect to nozzle 44 from a side surface. In this case, CPU 91 may determine whether a pickup error has occurred using images captured by the side camera.

In the above-described embodiment, production data 103A is edited on the machine by receiving the input of the operator from operation display section 80. However, production data 103A may be edited by remotely operating management device 100 or a PC, a tablet, or the like (not illustrated) connected to control device 60.

In the component mounting system of the present disclosure, the mounting control section may be configured to control the horizontal moving section and the lifting and lowering section such that the collection section starts to descend just before the mounting position and the collection section moves to the mounting position while descending, the first operation condition may be a condition for determining the operation trajectory such that the collection section starts to descend from a position closer to the mounting position when the distance is less than a predetermined distance than when the distance is equal to or greater than the predetermined distance and the collection section starts to descend from a position closer to the mounting position when the height of the other member is equal to or greater than a predetermined height than when the height of the other member is less than the predetermined height, and the second operation condition may be a condition for determining the operation trajectory such that the collection section starts to descend from a position closer to the mounting position when the height of the other member is equal to or greater than a predetermined height than when the height of the other member is less than the predetermined height, under the same condition as when the distance in the first operation condition is less than the predetermined distance. When the operation trajectory is determined based on the first operation condition, it is possible to determine the operation trajectory in which the movement distance is further shortened in consideration of the distance from the mounting position to the other member and the height of the other member, and, when the operation trajectory is determined based on the second operation condition, it is possible to set the operation trajectory in which no interference with the other member occurs even when the reliability of the distance to the other member is low.

In the component mounting system of the present disclosure, an editing section configured to edit the mounting position or a component size for each component based on an operation of an operator may be provided, and the determination section may determine an operation condition of the collection section as the first operation condition until editing is performed by the editing section, and, after editing is performed by the editing section, determine an operation condition of the collection section for a mounting target component to be mounted on the board after an editing target component that is a target of the editing as the second operation condition. When the operation trajectory of the collection section that has picked up the component edited by the editing section or the component to be mounted on the board thereafter is determined based on the first operation condition, the collection section and the other member may interfere with each other. This is because, by editing the mounting position and the component size, the component is mounted at a position different from a planned position, and the distance to the other member becomes different from a planned distance. Therefore, when the editing is performed by the editing section, it is significant to determine the operation trajectory of the collection section based on the second operation condition.

In addition, in the component mounting system of the present disclosure, a head having multiple collection sections, and a detection section configured to detect a collection error of the component in each of the multiple collection sections may be provided, the horizontal moving section may be capable of horizontally moving the head, the lifting and lowering section may be capable of individually lifting and lowering the multiple collection sections, and the mounting control section may collect the mounting target component into each of the multiple collection sections and subsequently perform the mounting operation, and the mounting control section may skip a mounting operation of a collection section in which the collection error is detected among the multiple collection sections and perform a mounting operation of a collection section in which the collection error is not detected, re-collect a component of the same type as a component that is not able to be mounted due to the collection error at a predetermined timing as the mounting target component, and perform the mounting operation by determining the operation trajectory while treating, as the pre-mounted component, components mounted on the board until a mounting operation of the re-collected mounting target component is performed after the mounting operation skip. Even when the mounting operation is skipped due to the collection error and the same type of component is re-collected and mounted thereafter, it is possible to avoid interference with the other member while shortening the movement distance of the collection section.

In this case, the determination section may determine an operation condition of the collection section in which the collection error is not detected among the multiple collection sections as the first operation condition, and determine an operation condition of the collection section in which the collection error is detected and which has re-collected the mounting target component among the multiple collection sections as the second operation condition. When the collection error is detected and the mounting target component is re-collected and mounted on the board, in a case where an operation trajectory of the collection section that has collected the component is determined based on the first operation condition, the component may interfere with the other member. This is because, when mounting the component that is the target of the collection error, there is a pre-mounted component on the board that would not be present in a case where the component is mounted in the initial order. Therefore, it is significant to determine the operation trajectory of the collection section based on the second operation condition when mounting the component that is the target of the collection error.

### INDUSTRIAL APPLICABILITY

The present disclosure can be used in the producing industry of the component mounting system and the like.

### REFERENCE SIGNS LIST

1: Component mounting system, 10, 10A to 10E: Component mounter, 12: Board, 20: Component supply device, 21: Reel, 22: Tape, 25: Board conveyance device, 26: Conveyor belt, 27: Support pin, 28: Part camera, 29: Mark camera, 30: XY robot, 31: X-axis guide rail, 32: X-axis slider, 33: Y-axis guide rail, 34: Y-axis slider, 36: X-axis motor, 37: X-axis position sensor, 38, Y-axis motor, 39: Y-axis position sensor, 40: Head, 41: Head main body, 42: Nozzle holder, 42a: Engagement piece, 44: Nozzle, 46: Solenoid valve, 47: Negative pressure source, 48: Positive pressure source, 50: R-axis drive device, 51: R-axis shaft, 52: R-axis gear, 53: Gear, 54: R-axis motor, 55: R-axis position sensor, 60: Q-axis drive device, 61: Q-axis gear, 62: Q-axis gear, 63: Gear, 64: Gear, 65: Q-axis motor, 66: Q-axis position sensor, 70: Z-axis drive device, 71: Z-axis slider, 71a: Clamping section, 72: Ball screw, 73: Z-axis motor, 74: Z-axis position sensor, 80: Operation display section, 90: Control device, 91: CPU, 92: ROM, 93: Storage, 94: RAM, 100: Management device, 101: CPU, 102: ROM, 103A: Production data, 103B: First operation trajectory determination table, 103C: Second operation trajectory determination table, 104: RAM, H, Hα, Hβ, Hγy: Height, L, Lα, Lβ, Lγ: Distance, O1: First operation trajectory, O2: Second operation trajectory, O3: Third operation trajectory, O4: Fourth operation trajectory, O5: Fifth operation trajectory, P: Component

1. A component mounting system for mounting a component on a board, the component mounting system comprising:
a collection section configured to collect a mounting target component;
a horizontal moving section configured to move the collection section horizontally;
a lifting and lowering section configured to lift and lower the collection section;
a determination section configured to determine, as an operation condition for determining an operation trajectory that is a combination of descending and horizontal movement of the collection section when mounting the mounting target component at a mounting position on the board, one of multiple operation conditions including a first operation condition for determining the operation trajectory such that the mounting target component does not interfere with another member including a pre-mounted component mounted on the board before the mounting target component based on a height of the other member and a distance from the mounting position to a position of the other member, and a second operation condition for determining the operation trajectory such that the mounting target component does not interfere with the other member, regardless of the distance from the mounting position to the position of the other member, based on the height of the other member; and
a mounting control section configured to determine the operation trajectory based on the operation condition determined by the determination section and perform a mounting operation for controlling the horizontal moving section and the lifting and lowering section such that the collection section operates in accordance with the determined operation trajectory to mount the mounting target component at the mounting position.

2. The component mounting system according to claim 1,
wherein the operation trajectory includes an operation trajectory in which the collection section starts to descend just before the mounting position and the collection section moves to the mounting position while descending,
the first operation condition is a condition for determining the operation trajectory such that the collection section starts to descend from a position closer to the mounting position when the distance is less than a predetermined distance than when the distance is equal to or greater than the predetermined distance and the collection section starts to descend from a position closer to the mounting position when the height of the other member is equal to or greater than a predetermined height than when the height of the other member is less than the predetermined height, and
the second operation condition is a condition for determining the operation trajectory such that the collection section starts to descend from a position closer to the mounting position when the height of the other member is equal to or greater than a predetermined height than when the height of the other member is less than the predetermined height, under the same condition as when the distance in the first operation condition is less than the predetermined distance.

3. The component mounting system according to claim 1, further comprising:
an editing section configured to edit the mounting position or a component size for each component based on an operation of an operator,
wherein the determination section determines an operation condition of the collection section as the first operation condition until editing is performed by the editing section, and, after editing is performed by the editing section, determines an operation condition of the collection section for a mounting target component to be mounted on the board after an editing target component that is a target of the editing as the second operation condition.

4. The component mounting system according to claim 1, further comprising:
a head having multiple collection sections; and
a detection section configured to detect a collection error of the component in each of the multiple collection sections,
wherein the horizontal moving section is capable of horizontally moving the head,
the lifting and lowering section is capable of individually lifting and lowering the multiple collection sections, and
the mounting control section collects the mounting target component into each of the multiple collection sections and subsequently performs the mounting operation, and the mounting control section skips a mounting operation of a collection section in which the collection error is detected among the multiple collection sections and performs a mounting operation of a collection section in which the collection error is not detected, re-collects a component of the same type as a component that is not able to be mounted due to the collection error at a predetermined timing as the mounting target component, and performs the mounting operation by determining the operation trajectory while treating, as the pre-mounted component, components mounted on the board until a mounting operation of the re-collected mounting target component is performed after the mounting operation skip.

5. The component mounting system according to claim 4, wherein the determination section determines an operation condition of the collection section in which the collection error is not detected among the multiple collection sections as the first operation condition, and determines an operation condition of the collection section in which the collection error is detected and which has re-collected the mounting target component among the multiple collection sections as the second operation condition.
